(19) United States
(12) Patent Application Publication
(10) Pub. No.: US 2024/0126945 A1
(43) Pub. Date: Apr. 18, 2024

(54) GENERATING A MODEL OF A TARGET ENVIRONMENT BASED ON INTERACTIONS OF AN AGENT WITH SOURCE ENVIRONMENTS

(71) Applicant: DeepMind Technologies Limited, London (GB)

(72) Inventors: Alexis Bellot, London (GB); Alan John Malek, London (GB); Silvia Chiappa, Cambridge (GB)

(21) Appl. No.: 18/379,988

(22) Filed: Oct. 13, 2023

Related U.S. Application Data
(60) Provisional application No. 63/415,904, filed on Oct. 13, 2022.

(51) Int. Cl. G06F 30/20; G06F 16/901

(52) U.S. Cl. CPC G06F 30/20; G06F 16/9024

(57) ABSTRACT

Methods, systems, and apparatus, including computer programs encoded on a computer storage medium, for selecting actions for an agent in a target environment. In particular, the actions are selected using an environment model for the target environment that is parameterized using interactions of the agent with the target environment and one or more source environments.

### CROSS-REFERENCE TO RELATED APPLICATION

This application claims priority under 35 U.S.C. 119 to Provisional Application No. 63/415,904, filed Oct. 13, 2022, which is incorporated by reference.

### BACKGROUND

This specification relates to selecting actions to control an agent interacting with an environment.

Controlling an agent interacting with an environment requires decision-making under uncertainty. The agent must navigate the trade-off between learning about reward distributions by exploring the effects of actions versus exploiting the most promising actions based on the current interaction history of the agent with the environment.

### SUMMARY

This specification generally describes a system implemented as computer programs on one or more computers in one or more locations that parameterizes an environment model of a target environment using interaction data from both the target environment and from one or more source environments that are each different from the target environment.

The system uses the environment model to control the agent in the target environment. Thus, information from the one or more source environments is used to improve the quality of the actions selected in the target environment.

According to one aspect, there is provided a method performed by one or more computers, the method comprising: selecting actions to be performed by an agent to interact with a target environment over a sequence of time steps using an environment model, wherein the environment model is parameterized by a set of environment model parameters defining a model of the target environment, wherein for each time step, selecting an action to be performed by the agent at the time step comprises: sampling current values of the set of environment model parameters in accordance with a probability distribution, wherein the probability distribution is derived from a set of interaction history data, wherein the set of interaction history data comprises: (i) data characterizing interaction of the agent with the target environment at any preceding time steps in the sequence of time steps; and (ii) data characterizing interaction of the agent with each of one or more source environments, wherein each of the source environments are different than the target environment; generating, using the environment model and in accordance with the current values of the set of environment model parameters, a respective expected reward for each action in a set of actions that can be performed by the agent; and selecting the action to be performed by the agent at the time step based on the expected rewards.

In some implementations, sampling current values of the set of environment model parameters in accordance with the probability distribution comprises: generating respective values of the set of environment model parameters based on the set of interaction history data at each sampling iteration in a sequence of sampling iterations; and designating values of the set of environment model parameters generated at a particular sampling iteration in the sequence of sampling iterations as being sampled in accordance with the probability distribution.

In some implementations, the values of the set of environment model parameters generated at each sampling iteration in the sequence of sampling iterations define a Markov chain with an invariant distribution given by the probability distribution.

In some implementations, the method further comprises obtaining relationship data that characterizes a respective relationship between the target environment and each of the source environments; wherein at each sampling iteration, generating values of the set of environment model parameters based on the set of interaction history data comprises: generating values of the set of environment model parameters based on: (i) the set of interaction history data, and (ii) the relationship data.

In some implementations, the target environment and each of the source environments can be represented by respective graphs; and wherein for each source environment, the relationship data defines a correspondence between one or more nodes in the graph representing the target environment with corresponding nodes in the graph representing the source environment.

In some implementations, each node in the graph representing the target environment represents a respective element of the target environment.

In some implementations, one or more nodes in the graph representing the target environment represent respective features of the target environment.

In some implementations, a first node in the graph representing the target environment represents respective actions performed by the agent in the target environment.

In some implementations, a second node in the graph representing the target environment represents respective rewards received as a result of actions performed by the agent in the target environment.

In some implementations, at each sampling iteration, generating values of the set of environment model parameters based on: (i) the set of interaction history data, and (ii) the relationship data comprises, for each of one or more environment model parameter: designating one or more of the source environments as being relevant to the environment model parameter using the relationship data; and generating the value of the environment model parameter based at least in part on data characterizing interaction of the agent with each of the one or more source environments designated as being relevant to the environment model parameter.

In some implementations, designating one or more of the source environments as being relevant to the environment model parameter using the relationship data comprises: determining that the environment model parameter is associated with a node in the graph representing the target environment; determining, using the relationship data, that the node in the graph representing the target environment has a relationship with a corresponding node in a graph representing a source environment; and in response, designating the source environment as being relevant to the environment model parameter.

In some implementations, the method further comprises, at each time step: augmenting the set of interaction history data with data characterizing interaction of the agent with the target environment at the time step.

In some implementations, for each time step, selecting the action to be performed by the agent at the time step based on the expected rewards comprises: selecting an action having a highest expected reward from among the set of actions.

In some implementations, for each time step, selecting the action to be performed by the agent at the time step based on the expected rewards comprises: determining a probability distribution over the set of actions using the expected rewards; and sampling an action in accordance with the probability distribution over the set of actions.

In some implementations, for each source environment, the data characterizing the interaction of the agent with the source environment comprises a plurality of experience tuples, wherein each experience tuple comprises: (i) an observation characterizing a state of the source environment, (ii) an action performed by the agent in response to the observation; and (iii) a reward received by the agent as a result of performing the action.

In another aspect, there is provided a system comprising: one or more computers; and one or more storage devices communicatively coupled to the one or more computers, wherein the one or more storage devices store instructions that, when executed by the one or more computers, cause the one or more computers to perform operations of the methods described herein.

One or more non-transitory computer storage media storing instructions that when executed by one or more computers cause the one or more computers to perform operations of the methods described herein.

Particular embodiments of the subject matter described in this specification can be implemented so as to realize one or more of the following advantages.

This specification describes a system for selecting actions to control an agent interacting with a “target” environment, e.g., to perform a task in the target environment. To select actions to be performed by the agent, the system can implement a model of the target environment that can be used to predict the expected rewards that will result from the agent performing various actions in the target environment. The system can derive values of a set of parameters of the model of the target environment based at least in part on data characterizing interactions of the agent with different but related “source” environments.

In particular, the system can leverage interaction data from source environments to more rapidly and accurately learn a model of the target environment, which the system can use to enable the agent to perform tasks in the target environment more effectively. The system can thus enable more efficient use of resources, e.g., by requiring fewer interactions of the agent with the target environment in order to learn an action selection policy for controlling the agent in the target environment. Resources can include, e.g., physical resources (e.g., energy, electricity, oil, etc.), computational resources (e.g., memory, computing power, etc.), or any other appropriate resources.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 shows an example action selection system.

FIG. 2 shows an example of partial transportability between the target environment and two source environment.

FIG. 3 is a flow diagram of an example process for selecting actions to be performed by the agent in the target environment.

FIG. 4 shows an example of performing a sampling iteration.

Like reference numbers and designations in the various drawings indicate like elements.

### DETAILED DESCRIPTION

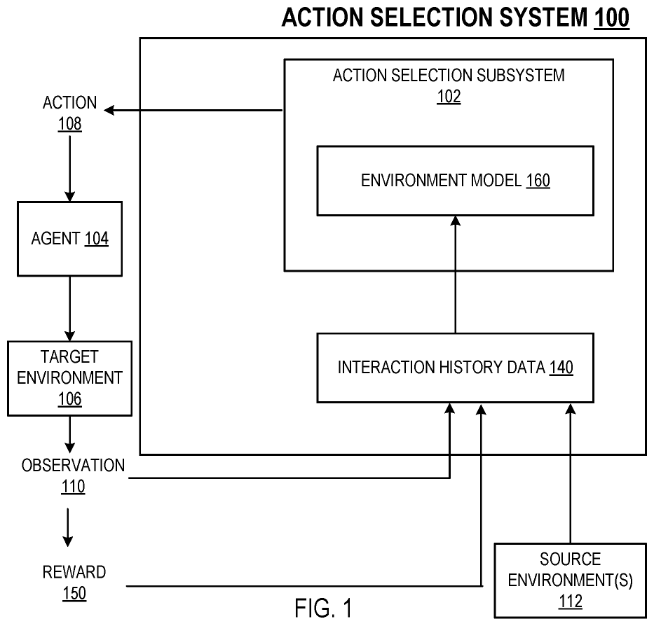

FIG. 1 shows an example action selection system 100. The action selection system 100 is an example of a system implemented as computer programs on one or more computers in one or more locations in which the systems, components, and techniques described below are implemented.

The action selection system 100 uses an action selection subsystem 102 to control an agent 104 interacting with a target environment 106 to accomplish a task by selecting actions 108 to be performed by the agent 104 at each of multiple time steps in a sequence of time steps.

For example, the sequence of time steps can continue indefinitely, can continue for a predetermined number of time steps, or can continue until the target environment 106 enters a designated terminal state.

Examples of agents, environments, and tasks will be described below.

At each time step during any given task episode, the system 100 selects an action 108 to be performed by the agent 104 at the time step.

After the agent performs the action 108 at the time step, the environment 106 transitions into a new state and the system 100 receives an observation 110 characterizing the state of the environment 106 at the time step.

The observation 110 can include any appropriate information that characterizes the state of the environment. As one example, the observation 110 can include sensor readings from one or more sensors configured to sense the environment. For example, the observation 110 can include one or more images captured by one or more cameras, measurements from one or more proprioceptive sensors, and so on. Examples of observations will also be described in more detail below.

In some cases, the system 100 receives a reward 150 from the environment in response to the agent performing the action.

Generally, the reward 150 is a scalar numerical value and characterizes a progress of the agent towards completing the task.

As a particular example, the reward can be a sparse binary reward that is zero unless the task is successfully completed and one if the task is successfully completed as a result of the action performed.

As another particular example, the reward can be a dense reward that measures a progress of the agent towards completing the task as of individual observations received during the episode of attempting to perform the task, i.e., so that non-zero rewards can be and frequently are received before the task is successfully completed.

As described above, the system 100 controls the agent 104 using an action selection subsystem 102.

The action selection subsystem 102 maintains an environment model 160 of the target environment 106 and uses the environment model 160 to select the action to be performed by the agent at each time step in the sequence.

The environment model 160 is a model of acting in the environment, i.e., that maps actions in a set of actions that can be performed by the agent to expected rewards.

That is, at any given time step in the sequence, the environment model 160 maps each action to a respective estimated reward that would be received if the agent performed the action at the given time step.

More specifically, the system 100 maintains interaction history data 140 and, at each time step, uses the interaction history data 140 to parameterize the environment model 160, i.e., to assign respective current values to each of a set of parameters of the environment model and, therefore, to define the mapping of actions to expected rewards.

At any given time step, the interaction history data 140 includes data characterizing interaction of the agent with the target environment 106 at previous time steps in the sequence.

After the agent acts at a given time step and the system receives the observation and the reward, the system 100 updates the interaction history data 140 by augmenting the interaction history data 140 with data characterizing the interaction of the agent with the target environment 106 at the given time step.

In particular, the interaction history data 140 can include, for each preceding time step in the sequence, a tuple that identifies the action performed at the time step, the observation received at the time step, and the reward received at the time step.

The interaction history data 140 also includes data characterizing interaction of the agent with one or more source environments 112.

Each of the one or more source environments 112 is an environment that is different from the target environment 106 in some way. In other words, because of these differences, knowledge from any given source environment 112 is only partially transportable to the target environment 106. As used in this specification, “partially transportable” means that, while some information from a source environment is useful for successfully interacting with a target environment, other information is irrelevant to interacting with the target environment or does not accurately represent causality between variables, e.g., actions and rewards, within the target environment.

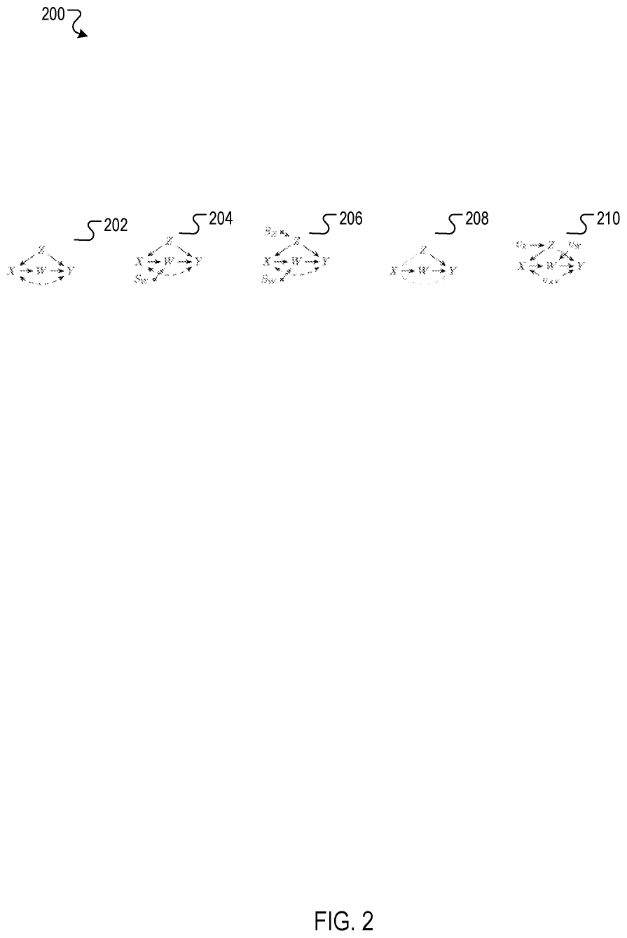

Examples of partial transportability are described in more detail below with reference to FIG. 2.

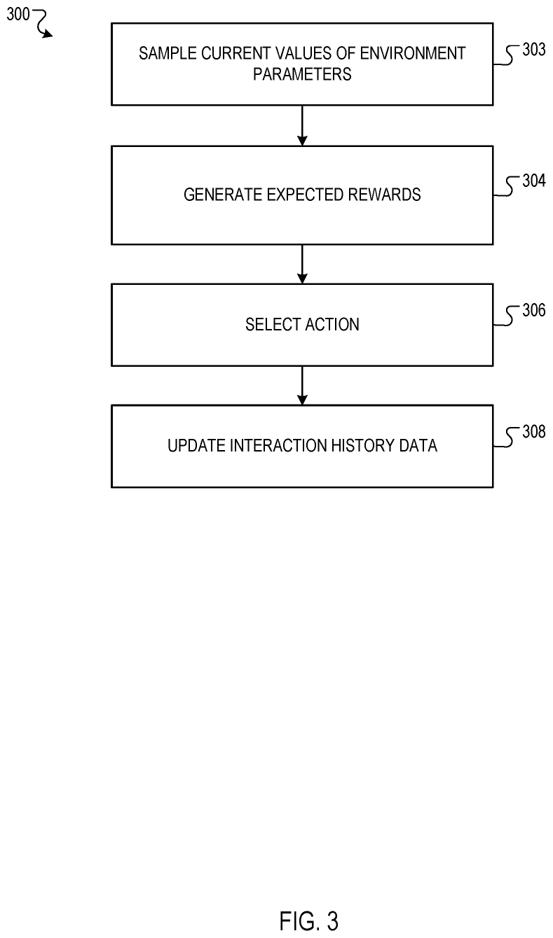

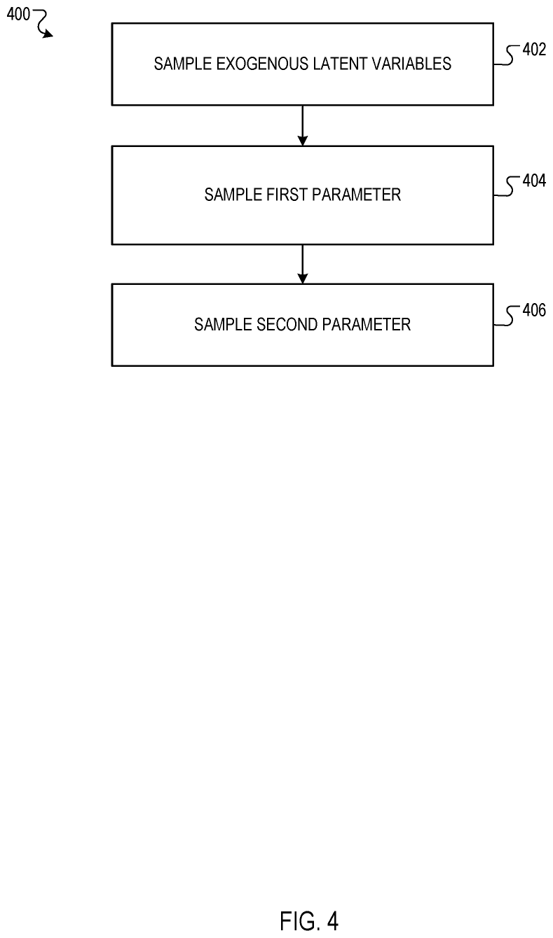

Using the interaction history data 140 to parametrize the environment model 160 of the target environment is described in more detail below with reference to FIGS. 3 and 4.

FIG. 2 shows an example 200 of partial transportability between the target and source environments.

In particular, FIG. 2 shows an example causal graph 210 of the target environment (π*).

The causal graph includes nodes and edges connecting nodes.

In particular, each node in the causal graph represents an element of the target environment. Generally, an element is a variable that can take different values for different states of the environment.

Examples of variables include actions X and rewards Y.

That is, the causal graph includes nodes representing actions X and rewards Y. In other words, the causal graph includes a node that represents actions performed by the agent in the target environment and a node that represents rewards received by the agent as a result of actions performed by the agent in the target environment.

The causal graph also includes nodes representing other variables of the target environment that have an impact on the actions X performed by the agent, the rewards Y, or both. For example, one or more nodes in the graph can represent respective additional endogenous, observed features, e.g., those that are included in observations received by the system.

In the example graph 210, the graph also includes nodes representing elements W and Z. Nodes and elements or features or variables represented by the nodes will be referred to interchangeably in this specification.

More generally, the causal graph includes nodes representing endogenous observed variables V that include the variables X, Y, Wand Z.

The target environment also includes exogenous latent variables U that are not observable by the system and therefore not shown in the graph 210. The exogenous latent variables U are associated with a probability distribution P(U) that reflects the system's uncertainty in the values of the exogenous latent variables at any given time step, i.e., because the exogenous latent variables are unobservable.

An example of the impact of exogenous latent variables U on the graph 210 is shown in a latent graph 250 and described below.

In the causal graph 210 of the target environment, there is a directed edge from a node V to a node W if V appears as an argument in ƒ_{W}, where f_{W} is a function that determines values of the variable W and takes as arguments one or more variables in V, U, or both. Arguments for the function f_{W} that are in V are referred to as pa_{W} and arguments for the function f_{W} that are in U are referred to as u_{W}.

That is, each node N in the causal graph is associated with a function f_{N}. The function f_{N} maps a set of arguments to a value of the variable represented by the node N. Arguments for the function f_{N} that are in V are referred to as pa_{N} and arguments for the function f_{N} that are in U are referred to as u_{N}.

While the system may have information identifying which variables influence the value of the node N, i.e., so that the set of arguments for the function f_{N} is known, before controlling the agent in the target environment, the system may not have information identifying the mapping from values of variables in the set of arguments for the function f_{N} to values of the variable N.

Thus, the fact that there is a directed edge from each of W and Z to Y means that the values of W and of Z impact the reward received for a given action.

Additionally, there is a bi-directional edge between two nodes V and W in the causal graph 210 if the union of U_{V} and U_{W} is non-empty, where U_{V} is the set of exogenous latent variables in ƒ_{V} and U_{W} is the set of exogenous latent variables in ƒ_{W}.

Thus, two nodes being connected by a bi-directional edge means that the two nodes share an unobserved confounder from the set of exogenous variables U.

For example, the fact that there is a bi-directional edge between X and Y means that there is an unobserved confounder in U that impacts both the value of the action and the value of the reward at any given time step.

As indicated above, the source environments, while related to the target environment in some way, differ from the target environment in certain respects.

These differences can be represented in a selection diagram. A selection diagram between a source environment and a target environment is a causal graph that includes the nodes and edges from the causal graph of the target environment and also includes selection nodes pointing to one or more nodes in the causal graph of the target environment that indicate where discrepancies between the two corresponding environments, i.e., the target environment and the corresponding source environment, may take place.

FIG. 2 shows an example selection diagram 220 representing differences between the target environment π* and a source environment π^{a}.

As can be seen from the diagram 220, the diagram 220 is the same as the graph 210, except that there exists a selection node Sw that points to the node W in the diagram 220.

This indicates that W represents a variable for which (1) the arguments to the function ƒ_{W} are different between the source environment and the target environment, i.e., the functional assignments for the node W are not invariant across the source and target environments. In some cases, selection nodes can also be included when (2) the probability distributions for one or more of the exogenous variables in the set of arguments to the function ƒ_{W} are different between the source environment and the target environment.

In other words, the diagram 220 shows that the target and source environment differ in that the causal mechanism governing values of the variable W differs between the source and target environment while all other causal relationships are the same.

FIG. 2 also shows another example selection diagram 230 representing differences between the target environment π*and another source environment π^{b}.

As can be seen from the diagram 230, the diagram 230 is the same as the graph 210, except that there exists a selection node Sw that points to the node W in the diagram 230 and a selection node S_{Z} that points to the node Z in the diagram 230. The presence of the selection node S_{Z} indicates that Z represents a variable for which (1) the arguments to the function ƒ_{Z} are different between the source environment and the target environment or (2) the probability distributions for one or more of the exogenous variables in the set of arguments to the function ƒ_{Z} are different between the source environment and the target environment or (3) both.

In other words, the diagram 230 shows that the target and source environment differ in that the causal mechanism governing values of the variables W and Z differ between the source and target environment while all other causal relationships are the same.

Thus, different ones of the source environments can differ from the target environment in different ways, impacting the causal relationships between variables (observed or unobserved) between the two environments. This can make directly using an environment model for any one of the source environments to control the agent in the target environment undesirable, especially if the causal relationships in the target environment are not yet known.

In other words, the knowledge of the causal effects of actions from the source environments is only partially transportable from the source environments to the target environment, because not all of the causal mechanisms governing the values of the variables in the environment are the same between the source and target environments. Thus, relying on causal effects observed in a given source environment to act in the target environment can be problematic.

These differences between environments can arise for any of a variety of reasons.

For example, the target environment and the source environments can be respective (real or simulated) medical environments that each include a respective population of subjects. A “subject” can be, e.g., a cell, a collection of cells, an animal (e.g., a mouse, a rat, a cat, a dog, etc.), or a person. In each environment, the agent can perform actions from a set of actions that include one or more medical treatment actions. Each medical treatment action can correspond to causing a respective medical treatment (e.g., a particular level of a drug, or a particular therapy) to be applied (e.g., administered) to a subject. For example, there can be a single medical treatment and the actions can include one action that applies the treatment and another action that does not apply the treatment to the given subject. As another example, there can be multiple medical treatments and different actions can apply different medical treatments to the given subject with, optionally, one of the actions resulting in no treatment being applied to the given subject.

The agent can receive a reward as a result of selecting a medical treatment action, e.g., based on a result of applying the corresponding medical treatment to a subject, e.g., based on a change in one or more physiological parameters of the subject (e.g., gene expression levels, cholesterol levels, blood sugar levels, etc.), based on a level of side effects experienced by the subject from the medical treatment, or based on any other appropriate aspect of the response of the subject to receiving the medical treatment.

Thus, in the case of medical environment, the agent can be considered to be a software agent that selects the medical treatment (if any) to be applied to the given subject and the treatment is then applied by another agent, e.g., by the given subject, by a clinician, or by an automated treatment mechanism, according to instructions provided by the agent.

The observations in these cases can include features that characterize the given subject that is being considered for treatment at the current time step and, optionally, features characterizing the medical environment at the current time step.

Source medical environments can differ from a target medical environment in any of a variety of possible ways. For instance, a population of subjects in a source environment may have different demographic characteristics than a population of subjects in the target environment, thereby impacting the causal mechanisms that govern the rewards received as a result of apply a particular treatment to a subject. As another example, when the source and target medical environments are in different real-world regions, e.g., different hospitals or other medical facilities, environmental factors can cause different probability distributions across values of a variety of latent variables, thereby impacting the causal mechanisms.

As another example, the target environment and the source environment(s) can be respective environments for controlling a mechanical agent, e.g., an autonomous vehicle or a robot. In this example, a source environment can include additional elements (e.g., objects, agents, etc.) that are not included in the target environment. As another example, a source environment can exclude elements (e.g., objects, agents, etc.) that are included in the target environment. This can then impact the effect of actions performed by the agent in the environment. As another example, a source environment can differ from a target environment based on environment conditions such as wind speed, temperature, altitude, gravity, lighting, etc, impacting the environment dynamics. As another example, agents in a source environment can behave differently from agents in a target environment, e.g., by moving at different speeds, or by performing different tasks. As another example, the source environments can be simulated environments while the target environment can be a real-world environment that is imperfectly simulated by the simulated environments.

As yet another example, the target environment and the source environment(s) can be respective industrial facilities and the agent can perform actions for controlling the industrial facility. In this example, a source environment can include additional elements (e.g., objects, agents, etc.) that are not included in the target environment. As another example, a source environment can exclude elements (e.g., objects, agents, etc.) that are included in the target environment. This can then impact the effect of actions performed by the agent in the environment. As another example, a source environment can differ from a target environment based on environment conditions of the real-world region where the industrial facility is located, such as wind speed, temperature, altitude, gravity, lighting, etc, impacting the environment dynamics. As another example, the source environments can be simulated environments while the target environment can be a real-world environment that is imperfectly simulated by the simulated environments.

As yet another example, the target environment and the source environments can be respective content recommendation environments, and the agent can perform actions for providing content recommendations to users. A content recommendation environment can refer to an environment where one or more users can select content items, e.g., videos, or books, or products. In this example, the source environment can include a different set of content items than those that are available in the target environment, or the source environment can be interacted with by a different set of users than the target environment, and so forth.

By controlling the agent using the interaction history data, the system can effectively control the agent to leverage the similarity between the source and target environments while accounting for the differences.

Further examples of agents, environments, and observations are described next.

In some implementations, the environment is a real-world environment, the agent is a mechanical agent interacting with the real-world environment, e.g., a robot or an autonomous or semi-autonomous land, air, or sea vehicle operating in or navigating through the environment, and the actions are actions taken by the mechanical agent in the real-world environment to perform the task. For example, the mechanical agent, e.g. robot, may be interacting with the environment to accomplish a specific task, e.g., to locate or manipulate an object of interest in the environment or to move an object of interest to a specified location in the environment or to navigate to a specified destination in the environment.

In these implementations, the observations may include, e.g., one or more of: images, object position data, and sensor data to capture observations as the agent interacts with the environment, for example sensor data from an image, distance, or position sensor or from an actuator. For example in the case of a robot, the observations may include data characterizing the current state of the robot, e.g., one or more of: joint position, joint velocity, joint force, torque or acceleration, e.g., gravity-compensated torque feedback, and global or relative pose of an item held by the robot. In the case of a robot or other mechanical agent or vehicle the observations may similarly include one or more of the position, linear or angular velocity, force, torque or acceleration, and global or relative pose of one or more parts of the agent. The observations may be defined in 1, 2 or 3 dimensions, and may be absolute and/or relative observations. The observations may also include, for example, sensed electronic signals such as motor current or a temperature signal; and/or image or video data for example from a camera or a LIDAR sensor, e.g., data from sensors of the agent or data from sensors that are located separately from the agent in the environment.

In these implementations, the actions may be control signals to control the robot or other mechanical agent, e.g., torques for the joints of the robot or higher-level control commands, or the autonomous or semi-autonomous land, air, sea vehicle, e.g., torques to the control surface or other control elements e.g. steering control elements of the vehicle, or higher-level control commands. The control signals can include for example, position, velocity, or force/torque/acceleration data for one or more joints of a robot or parts of another mechanical agent. The control signals may also or instead include electronic control data such as motor control data, or more generally data for controlling one or more electronic devices within the environment the control of which has an effect on the observed state of the environment. For example in the case of an autonomous or semi-autonomous land or air or sea vehicle the control signals may define actions to control navigation e.g. steering, and movement e.g., braking and/or acceleration of the vehicle.

In some implementations the environment is a simulation of the above-described real-world environment, and the agent is implemented as one or more computers interacting with the simulated environment. For example the simulated environment may be a simulation of a robot or vehicle and the reinforcement learning system may be trained on the simulation and then, once trained, used in the real-world.

In some implementations the environment is a real-world manufacturing environment for manufacturing a product, such as a chemical, biological, or mechanical product, or a food product. As used herein a “manufacturing” a product also includes refining a starting material to create a product, or treating a starting material e.g. to remove pollutants, to generate a cleaned or recycled product. The manufacturing plant may comprise a plurality of manufacturing units such as vessels for chemical or biological substances, or machines, e.g. robots, for processing solid or other materials. The manufacturing units are configured such that an intermediate version or component of the product is moveable between the manufacturing units during manufacture of the product, e.g. via pipes or mechanical conveyance. As used herein manufacture of a product also includes manufacture of a food product by a kitchen robot.

The agent may comprise an electronic agent configured to control a manufacturing unit, or a machine such as a robot, that operates to manufacture the product. That is, the agent may comprise a control system configured to control the manufacture of the chemical, biological, or mechanical product. For example the control system may be configured to control one or more of the manufacturing units or machines or to control movement of an intermediate version or component of the product between the manufacturing units or machines.

As one example, a task performed by the agent may comprise a task to manufacture the product or an intermediate version or component thereof. As another example, a task performed by the agent may comprise a task to control, e.g. minimize, use of a resource such as a task to control electrical power consumption, or water consumption, or the consumption of any material or consumable used in the manufacturing process.

The actions may comprise control actions to control the use of a machine or a manufacturing unit for processing a solid or liquid material to manufacture the product, or an intermediate or component thereof, or to control movement of an intermediate version or component of the product within the manufacturing environment e.g. between the manufacturing units or machines. In general the actions may be any actions that have an effect on the observed state of the environment, e.g. actions configured to adjust any of the sensed parameters described below. These may include actions to adjust the physical or chemical conditions of a manufacturing unit, or actions to control the movement of mechanical parts of a machine or joints of a robot. The actions may include actions imposing operating conditions on a manufacturing unit or machine, or actions that result in changes to settings to adjust, control, or switch on or off the operation of a manufacturing unit or machine.

The rewards or return may relate to a metric of performance of the task. For example in the case of a task that is to manufacture a product the metric may comprise a metric of a quantity of the product that is manufactured, a quality of the product, a speed of production of the product, or to a physical cost of performing the manufacturing task, e.g. a metric of a quantity of energy, materials, or other resources, used to perform the task. In the case of a task that is to control use of a resource the metric may comprise any metric of usage of the resource.

In general observations of a state of the environment may comprise any electronic signals representing the functioning of electronic and/or mechanical items of equipment. For example a representation of the state of the environment may be derived from observations made by sensors sensing a state of the manufacturing environment, e.g. sensors sensing a state or configuration of the manufacturing units or machines, or sensors sensing movement of material between the manufacturing units or machines. As some examples such sensors may be configured to sense mechanical movement or force, pressure, temperature; electrical conditions such as current, voltage, frequency, impedance; quantity, level, flow/movement rate or flow/movement path of one or more materials; physical or chemical conditions e.g. a physical state, shape or configuration or a chemical state such as pH; configurations of the units or machines such as the mechanical configuration of a unit or machine, or valve configurations; image or video sensors to capture image or video observations of the manufacturing units or of the machines or movement; or any other appropriate type of sensor. In the case of a machine such as a robot the observations from the sensors may include observations of position, linear or angular velocity, force, torque or acceleration, or pose of one or more parts of the machine, e.g. data characterizing the current state of the machine or robot or of an item held or processed by the machine or robot. The observations may also include, for example, sensed electronic signals such as motor current or a temperature signal, or image or video data for example from a camera or a LIDAR sensor. Sensors such as these may be part of or located separately from the agent in the environment.

In some implementations the environment is the real-world environment of a service facility comprising a plurality of items of electronic equipment, such as a server farm or data center, for example a telecommunications data center, or a computer data center for storing or processing data, or any service facility. The service facility may also include ancillary control equipment that controls an operating environment of the items of equipment, for example environmental control equipment such as temperature control e.g. cooling equipment, or air flow control or air conditioning equipment such as a heater, a cooler, a humidifier, or other hardware that modifies a property of air in the real-world environment. The task may comprise a task to control, e.g. minimize, use of a resource, such as a task to control electrical power consumption, or water consumption. The agent may comprise an electronic agent configured to control operation of the items of equipment, or to control operation of the ancillary, e.g. environmental, control equipment.

In general the actions may be any actions that have an effect on the observed state of the environment, e.g. actions configured to adjust any of the sensed parameters described below. These may include actions to control, or to impose operating conditions on, the items of equipment or the ancillary control equipment, e.g. actions that result in changes to settings to adjust, control, or switch on or off the operation of an item of equipment or an item of ancillary control equipment.

In general observations of a state of the environment may comprise any electronic signals representing the functioning of the facility or of equipment in the facility. For example a representation of the state of the environment may be derived from observations made by any sensors sensing a state of a physical environment of the facility or observations made by any sensors sensing a state of one or more of items of equipment or one or more items of ancillary control equipment. These include sensors configured to sense electrical conditions such as current, voltage, power or energy; a temperature of the facility; fluid flow, temperature or pressure within the facility or within a cooling system of the facility; or a physical facility configuration such as whether or not a vent is open.

The rewards or return may relate to a metric of performance of the task. For example in the case of a task to control, e.g. minimize, use of a resource, such as a task to control use of electrical power or water, the metric may comprise any metric of use of the resource.

In some implementations the environment is the real-world environment of a power generation facility e.g. a renewable power generation facility such as a solar farm or wind farm. The task may comprise a control task to control power generated by the facility, e.g. to control the delivery of electrical power to a power distribution grid, e.g. to meet demand or to reduce the risk of a mismatch between elements of the grid, or to maximize power generated by the facility. The agent may comprise an electronic agent configured to control the generation of electrical power by the facility or the coupling of generated electrical power into the grid. The actions may comprise actions to control an electrical or mechanical configuration of an electrical power generator such as the electrical or mechanical configuration of one or more renewable power generating elements e.g. to control a configuration of a wind turbine or of a solar panel or panels or mirror, or the electrical or mechanical configuration of a rotating electrical power generation machine. Mechanical control actions may, for example, comprise actions that control the conversion of an energy input to an electrical energy output, e.g. an efficiency of the conversion or a degree of coupling of the energy input to the electrical energy output. Electrical control actions may, for example, comprise actions that control one or more of a voltage, current, frequency or phase of electrical power generated.

The rewards or return may relate to a metric of performance of the task. For example in the case of a task to control the delivery of electrical power to the power distribution grid the metric may relate to a measure of power transferred, or to a measure of an electrical mismatch between the power generation facility and the grid such as a voltage, current, frequency or phase mismatch, or to a measure of electrical power or energy loss in the power generation facility. In the case of a task to maximize the delivery of electrical power to the power distribution grid the metric may relate to a measure of electrical power or energy transferred to the grid, or to a measure of electrical power or energy loss in the power generation facility.

In general observations of a state of the environment may comprise any electronic signals representing the electrical or mechanical functioning of power generation equipment in the power generation facility. For example a representation of the state of the environment may be derived from observations made by any sensors sensing a physical or electrical state of equipment in the power generation facility that is generating electrical power, or the physical environment of such equipment, or a condition of ancillary equipment supporting power generation equipment. Such observations may thus include observations of wind levels or solar irradiance, or of local time, date, or season. Such sensors may include sensors configured to sense electrical conditions of the equipment such as current, voltage, power or energy; temperature or cooling of the physical environment; fluid flow; or a physical configuration of the equipment; and observations of an electrical condition of the grid e.g. from local or remote sensors. Observations of a state of the environment may also comprise one or more predictions regarding future conditions of operation of the power generation equipment such as predictions of future wind levels or solar irradiance or predictions of a future electrical condition of the grid.

As another example, the environment may be a chemical synthesis or protein folding environment such that each state is a respective state of a protein chain or of one or more intermediates or precursor chemicals and the agent is a computer system for determining how to fold the protein chain or synthesize the chemical. In this example, the actions are possible folding actions for folding the protein chain or actions for assembling precursor chemicals/intermediates and the result to be achieved may include, e.g., folding the protein so that the protein is stable and so that it achieves a particular biological function or providing a valid synthetic route for the chemical. As another example, the agent may be a mechanical agent that indirectly performs or controls the protein folding actions, or chemical synthesis steps, e.g. by controlling synthesis steps selected by the system automatically without human interaction. The observations may comprise direct or indirect observations of a state of the protein or chemical/intermediates/precursors and/or may be derived from simulation. Thus the system may be used to automatically synthesize a protein with a particular function such as having a binding site shape, e.g. a ligand that binds with sufficient affinity for a biological effect that it can be used as a drug. For example e.g. it may be an agonist or antagonist of a receptor or enzyme; or it may be an antibody configured to bind to an antibody target such as a virus coat protein, or a protein expressed on a cancer cell, e.g. to act as an agonist for a particular receptor or to prevent binding of another ligand and hence prevent activation of a relevant biological pathway.

In a similar way the environment may be a drug design environment such that each state is a respective state of a potential pharmaceutically active compound, i.e. a drug, and the agent is a computer system for determining elements of the pharmaceutically active compound and/or a synthetic pathway for the pharmaceutically active compound. The drug/synthesis may be designed based on a reward derived from a target for the pharmaceutically active compound, for example in simulation. The agent may be, or may include, a mechanical agent that performs or controls synthesis of the pharmaceutically active compound; and hence a process as described herein may include making such a pharmaceutically active compound.

For example the environment may be an in silico drug design environment, e.g., a molecular docking environment, and the agent may be a computer system for determining elements or a chemical structure of the drug. The drug may be a small molecule or biologic drug. An observation may be an observation of a simulated combination of the drug and a target of the drug. An action may be an action to modify the relative position, pose or conformation of the drug and drug target (or this may be performed automatically) and/or an action to modify a chemical composition of the drug and/or to select a candidate drug from a library of candidates. One or more rewards may be defined based on one or more of: a measure of an interaction between the drug and the drug target, e.g., of a fit or binding between the drug and the drug target; an estimated potency of the drug; an estimated selectivity of the drug; an estimated toxicity of the drug; an estimated pharmacokinetic characteristic of the drug; an estimated bioavailability of the drug; an estimated ease of synthesis of the drug; and one or more fundamental chemical properties of the drug. A measure of interaction between the drug and drug target may depend on e.g. a protein-ligand bonding, van der Waal interactions, electrostatic interactions, and/or a contact surface region or energy; it may comprise, e.g., a docking score. Following identification of elements or a chemical structure of a drug in simulation, the method may further comprise making the drug. The drug may be made partly or completely by an automatic chemical synthesis system.

In some applications the agent may be a software agent i.e. a computer program, configured to perform a task. For example the environment may be a circuit or an integrated circuit design or routing environment and the agent may be configured to perform a design or routing task for routing interconnection lines of a circuit or of an integrated circuit e.g. an ASIC. The reward(s) may then be dependent on one or more routing metrics such as interconnect length, resistance, capacitance, impedance, loss, speed or propagation delay; and/or physical line parameters such as width, thickness or geometry, and design rules. The reward(s) may also or instead include one or more reward(s) relating to a global property of the routed circuitry e.g. component density, operating speed, power consumption, material usage, a cooling requirement, level of electromagnetic emissions, and so forth. The observations may be e.g. observations of component positions and interconnections; the actions may comprise component placing actions e.g. to define a component position or orientation and/or interconnect routing actions e.g. interconnect selection and/or placement actions. The task may be, e.g., to optimize circuit operation to reduce electrical losses, local or external interference, or heat generation, or to increase operating speed, or to minimize or optimize usage of available circuit area. The method may include making the circuit or integrated circuit to the design, or with interconnection lines routed as determined by the method.

In some applications the agent is a software agent and the environment is a real-world computing environment. In one example the agent manages distribution of tasks across computing resources e.g. on a mobile device and/or in a data center. In these applications, the observations may include observations of computing resources such as compute and/or memory capacity, or Internet-accessible resources; and the actions may include assigning tasks to particular computing resources. The reward(s) may be configured to maximize or minimize one or more of: utilization of computing resources, electrical power, bandwidth, and computation speed.

In another example the software agent manages the processing, e.g. by one or more real-world servers, of a queue of continuously arriving jobs. The observations may comprise observations of the times of departures of successive jobs, or the time intervals between the departures of successive jobs, or the time a server takes to process each job, e.g. the start and end of a range of times, or the arrival times, or time intervals between the arrivals, of successive jobs, or data characterizing the type of job(s). The actions may comprise actions that allocate particular jobs to particular computing resources; the reward(s) may be configured to minimize an overall queueing or processing time or the queueing or processing time for one or more individual jobs, or in general to optimize any metric based on the observations.

As another example the environment may comprise a real-world computer system or network, the observations may comprise any observations characterizing operation of the computer system or network, the actions performed by the software agent may comprise actions to control the operation e.g. to limit or correct abnormal or undesired operation e.g. because of the presence of a virus or other security breach, and the reward(s) may comprise any metric(s) that characterizing desired operation of the computer system or network.

In some applications, the environment is a real-world computing environment and the software agent manages distribution of tasks/jobs across computing resources e.g. on a mobile device and/or in a data center. In these implementations, the observations may comprise observations that relate to the operation of the computing resources in processing the tasks/jobs, the actions may include assigning tasks/jobs to particular computing resources, and the reward(s) may relate to one or more metrics of processing the tasks/jobs using the computing resources, e.g. metrics of usage of computational resources, bandwidth, or electrical power, or metrics of processing time, or numerical accuracy, or one or more metrics that relate to a desired load balancing between the computing resources.

In some applications the environment is a data packet communications network environment, and the agent is part of a router to route packets of data over the communications network. The actions may comprise data packet routing actions and the observations may comprise e.g. observations of a routing table which includes routing metrics such as a metric of routing path length, bandwidth, load, hop count, path cost, delay, maximum transmission unit (MTU), and reliability. The reward(s) may be defined in relation to one or more of the routing metrics i.e. configured to maximize one or more of the routing metrics.

In some other applications the environment is an Internet or mobile communications environment and the agent is a software agent which manages a personalized recommendation for a user. The observations may comprise previous actions taken by the user, e.g. features characterizing these; the actions may include actions recommending items such as content items to a user. The reward(s) may be configured to maximize one or more of: an estimated likelihood that the user will respond favorably to being recommended the (content) item, a suitability unsuitability of one or more recommended items, a cost of the recommended item(s), and a number of recommendations received by the user, optionally within a time span.

As a further example, the actions may include presenting advertisements, the observations may include advertisement impressions or a click-through count or rate, and the reward may characterize previous selections of items or content taken by one or more users.

In some cases, the observations may include textual or spoken instructions provided to the agent by a third-party (e.g., an operator of the agent). For example, the agent may be an autonomous vehicle, and a user of the autonomous vehicle may provide textual or spoken instructions to the agent (e.g., to navigate to a particular location).

As another example the environment may be an electrical, mechanical or electro-mechanical design environment, e.g. an environment in which the design of an electrical, mechanical or electro-mechanical entity is simulated. The simulated environment may be a simulation of a real-world environment in which the entity is intended to work. The task may be to design the entity. The observations may comprise observations that characterize the entity, i.e. observations of a mechanical shape or of an electrical, mechanical, or electro-mechanical configuration of the entity, or observations of parameters or properties of the entity. The actions may comprise actions that modify the entity e.g. that modify one or more of the observations. The rewards or return may comprise one or more metric of performance of the design of the entity. For example rewards or return may relate to one or more physical characteristics of the entity such as weight or strength or to one or more electrical characteristics of the entity such as a measure of efficiency at performing a particular function for which the entity is designed. The design process may include outputting the design for manufacture, e.g. in the form of computer executable instructions for manufacturing the entity. The process may include making the entity according to the design. Thus the design of an entity may be optimized, e.g. by reinforcement learning, and then the optimized design output for manufacturing the entity, e.g. as computer executable instructions; an entity with the optimized design may then be manufactured.

As previously described the environment may be a simulated environment. Generally in the case of a simulated environment the observations may include simulated versions of one or more of the previously described observations or types of observations and the actions may include simulated versions of one or more of the previously described actions or types of actions. For example the simulated environment may be a motion simulation environment, e.g., a driving simulation or a flight simulation, and the agent may be a simulated vehicle navigating through the motion simulation. In these implementations, the actions may be control inputs to control the simulated user or simulated vehicle. Generally the agent may be implemented as one or more computers interacting with the simulated environment.

The simulated environment may be a simulation of a particular real-world environment and agent. For example, the system may be used to select actions in the simulated environment during training or evaluation of the system and, after training, or evaluation, or both, are complete, may be deployed for controlling a real-world agent in the particular real-world environment that was the subject of the simulation. This can avoid unnecessary wear and tear on and damage to the real-world environment or real-world agent and can allow the control neural network to be trained and evaluated on situations that occur rarely or are difficult or unsafe to re-create in the real-world environment. For example the system may be partly trained using a simulation of a mechanical agent in a simulation of a particular real-world environment, and afterwards deployed to control the real mechanical agent in the particular real-world environment. Thus in such cases the observations of the simulated environment relate to the real-world environment, and the selected actions in the simulated environment relate to actions to be performed by the mechanical agent in the real-world environment.

In some implementations the observations are observations of a real-world environment in which a human is performing a task, e.g. an image observation from an image sensor and/or a language observation from a speech recognition system; and the actions are language actions that control (instruct) the human, e.g. using natural language or images, to perform actions in the real-world environment to perform the task. A language action may be an action that outputs a natural language sentence, e.g. by defining a sequence of language tokens, e.g. words or wordpieces, to be emitted at sequential time steps.

Thus the agent may comprise a user interface device such as a digital device (a “digital assistant”), e.g. a smart speaker or smart display or other device, e.g. with a natural language input and/or output, that controls (instructs) a human user to perform a task. In general such a digital device can be a mobile device with a natural language interface to receive natural language requests from a human user and to provide natural language responses. It may also include a vision based input e.g. a camera and/or display screen. The digital device may include a language model or language generation neural network system either stored locally, or accessed remotely, or both. The user interface device may comprise, e.g., a mobile device, a keyboard (and optionally display), or a speech-based input mechanism, e.g. to input audio data characterizing a speech waveform of speech representing the input from the user in the natural or computer language and to convert the audio data into tokens representing the speech in the natural or computer language, i.e. representing a transcription of the spoken input. The user interface can also include a text or speech-based output, e.g. a display and/or a text-to-speech subsystem.

Thus in implementations the agent actions contribute to performing the task. A monitoring system, e.g. a video camera system, may be provided for monitoring the action (if any) which the user actually performs at each time step in case, e.g. due to human error, it is different from the action which the reinforcement learning system instructed the user to perform. The monitoring system can be used to determine whether the task has been completed. Training data may be collected by record the actions which the user actually performed based on the instruction. The reward value of an action may be generated, for example, by comparing the action the user took with a corpus of data showing a human expert performing the task, e.g. using techniques known from imitation learning, or in some other way, e.g. using a trained reward model. A system of this type can learn how to guide a human to perform a task, e.g. avoiding difficult to perform actions.

Optionally, in any of the above implementations, the observation at any given time step may include data from a previous time step that may be beneficial in characterizing the environment, e.g., the action performed at the previous time step, the reward received at the previous time step, or both.

FIG. 2 also shows an updated causal graph 240 of the target environment resulting from the agent performing an action. That is, as a result of an intervention on the variable X, i.e., by the system selecting an action to be performed by the agent, the value of the variable W can be impacted, because X is an argument in the function ƒ_{W}, and the value of the reward can be impacted, because W is an argument in the function ƒ_{Y}. The value of the reward is also impacted by the value of the variable Z, because Z is also an argument in the function ƒ_{Y}.

FIG. 2 also shows a causal graph 250 of the target environment that also shows exogenous variables U_{Z}, U_{W}, and U_{XY}. In other words, the causal graph 250 shows that there are respective exogenous variables in the arguments to the functions ƒ_{Z}, ƒ_{W}, ƒ_{X}, and ƒ_{Y}, with ƒ_{X} and ƒ_{Y} sharing the same exogenous variable as an argument, resulting in X and Y being connected with a bi-directional edge in the graph 210.

FIG. 3 is a flow diagram of an example process 300 for controlling the agent using the interaction history data. For convenience, the process 300 will be described as being performed by a system of one or more computers located in one or more locations. For example, an action selection system, e.g., the action selection system 100 of FIG. 1, appropriately programmed in accordance with this specification, can perform the process 300.

As described above, the system selects actions to be performed by an agent to interact with the target environment over a sequence of time steps using an environment model. The environment model is parameterized by a set of environment model parameters defining a model of the target environment. In other words, the environment model parameters define how the model determines the impact of actions on the environment, e.g., in terms of rewards received. In other words, the environment model is a model that can map a given action to an expected reward that will be received if the given action is performed by the agent given the previously-observed states of the environment.

Therefore, different values of the environment parameters can cause the environment model to map the given action to different expected rewards, even given the same history of previously-observed environment states. As indicated above, the previously observed environment states include information about values of endogenous variables but do not directly identify exogeneous variables, i.e., un-observable latent variables.

The system performs the following operations to control the agent at each time step in the sequence.

The system samples current values of the set of environment model parameters in accordance with a probability distribution (step 302).

The probability distribution is derived from a set of interaction history data. In other words, the system determines the probability distribution or, equivalently, a set of parameters defining or approximating the probability distribution, using the set of interaction history data as of the time step.

As described above, the interaction history data includes both (i) data characterizing interaction of the agent with the target environment at any preceding time steps in the sequence of time steps and (ii) data characterizing interaction of the agent with each of one or more source environments.

Generally, each source environment is a different environment from the target environment but may be leveraged by the system to improve the accuracy of the environment model.

More specifically, the interaction history data at time step t can be represented as {v̅, v̅ₜ} where v̅={v̅_{π}_{^{a}}, v̅_{π}_{^{b}}, . . . } and is the set of data characterizing interaction of the agent with each of the one or more source environments, i.e., environments π^{a}, π^{b}, and so on, and v̅ₜ=v̅ₓ_{⁽¹⁾}, v̅ₓ_{^{(t-1)}} and v̅ₓ_{^{(t-1)}} is data characterizing the interaction of the agent with the target environment at time step t-1.

The interaction history data generally includes, for any given time step (either during interaction with a source environment or the target environment), the set of endogenous variables at the time step. As a particular example, the interaction history data can include, for each time step, a tuple that includes the action performed at the time step, the observation at the time step, and the reward received at the time step.

Generally, the system generates an approximation of a probability distribution over values of the parameters of the environment model and then samples the values of the environment parameters from the approximation.

For example, the parameters of the environment can include a first set of parameters ξ and a second set of parameters θ.

In particular, the first set of parameters ξ are the parameters for the functions ƒ_{V} for the nodes V in the causal graph of the target environment and the second set of parameters θ are parameters for the exogenous probabilities of the exogenous variables U of the target environment.

That is, the first set of parameters 4 defines, for each node V in the causal graph, the possible functional assignments for the node V given possible values of the arguments to the function ƒ_{V}.

Thus, each parameter in the first set of parameters corresponds to a respective node in the causal graph of the target environment.

The second set of parameters θ defines, for each exogenous variable, the probability distribution over possible values of the exogenous variable. Thus, each parameter in the second set of parameters corresponds to a respective one of the exogenous variables.

The system can then generate, at a given time step t, an approximation of the probability distribution P (ξ, θ|{v̅, vₓ_{⁽¹⁾}, . . . , vₓ_{^{(t-1)}}}) and then sample ξ^{(t)}, θ^{(t)}˜P(ξ, θ|{v̅, vₓ_{⁽¹⁾}, . . . , vₓ_{^{(t-1)}}}.

That is, the system infers an approximation of the probability distribution P from the interaction history data, leveraging information from the source environments and past information from the target environment.

The system can apply the interaction history data to generate the approximation and to sample from the approximation in any of a variety of ways.

For example, the system can obtain relationship data that characterizes a respective relationship between the target environment and each of the source environments. In particular, the relationship data between the target environment and a given source environment can specify, for each variable that is represented by a node in the causal graph in the target environment, whether the causal mechanism for the variable is the same between the two environments.

In particular, as described above, in some cases, the target and source environments can be represented as respective causal graphs. In this example, the relationship data defines a correspondence between one or more nodes in the graph representing the target environment with corresponding nodes in the graph representing the source environment. In particular, the relationship data can indicate, for each node in the causal graph of the target environment, whether the node is pointed to by a selection node in the selection diagram between the source environment and the target environment because the arguments to the function for the node are different between the source environment and the target environment, i.e., the functional assignments for the node are not invariant across the source and target environments.

Thus, each node that does not have a selection node can be determined to have a corresponding node in the graph of the source environment, i.e., because the causal mechanism of the variable represented by the two nodes is the same across the environments.

The system can then use the relationship data to determine how to incorporate the history data for the source environments when generating the approximation.

As one example, the system can generate respective values of the set of environment model parameters based on the set of interaction history data at each sampling iteration in a sequence of sampling iterations and then designate values of the set of environment model parameters generated at a particular sampling iteration in the sequence of sampling iterations as being sampled in accordance with the probability distribution.

For example, the system can use a Gibbs sampler to carry out the sampling at each of the sampling iterations.

This is described below with reference to FIG. 4.

Thus, in this example, the values of the set of environment model parameters generated at each sampling iteration in the sequence of sampling iterations define a Markov chain with an invariant distribution given by the probability distribution. Thus, given that the invariant distribution is given by the probability distribution, the system can use the samples from an appropriate sampling iteration to approximate a sample from the probability distribution.

The system generates, using the environment model and in accordance with the current values of the set of environment model parameters, a respective expected reward for each action in a set of actions that can be performed by the agent (step 304).

That is, the system uses the current values of the parameters to define the functions ƒ for the node of the graph representing the expected reward Y and all parent nodes of the expected reward Y in the graph. The parent nodes of a particular node in the graph are all of the nodes that are on any possible directed path through the graph that ends at the particular node.

The system also uses the current values of the parameters to select values for any of the exogenous variables U that are arguments to any of the functions ƒ, e.g., by sampling in accordance with the parameters the value of exogenous variable.

The system then determines, for each action, the expected reward value by applying the functions to the selected action and the selected exogenous variable values to determine the expected reward.

The system selects the action to be performed by the agent at the time step based on the expected rewards (step 306). For example, the system can select the action with the highest expected reward. As another example, the system can map the expected rewards for the agents to probabilities, e.g., using a softmax function, and then sample an action using the respective probabilities.

After the agent performs the action, the system then updates the interaction history data (step 308). In particular, the system augments the set of interaction history data with data characterizing interaction of the agent with the target environment at the time step, e.g., the observation received at the time step after the agent performed the action, the received reward, and so on.

Updating the interaction history data can then result in different values of the environment model parameters being sampled at the next time step.

FIG. 4 is a flow diagram of an example process 400 for performing a sampling iteration at a given time step. For convenience, the process 400 will be described as being performed by a system of one or more computers located in one or more locations. For example, an action selection system, e.g., the action selection system 100 of FIG. 1, appropriately programmed in accordance with this specification, can perform the process 400.

Prior to performing the first sampling iteration, the system initializes values for the first set of parameters 4 and the second set of parameters θ. For example, the system can use the final values from the particular sampling iteration of the preceding time step or, for the first time step, use random values that fall within an appropriate range.

As a particular example, the system can represent, for each exogenous variable, the distribution over the values of the exogenous variables as a prior Dirichlet distribution, so that exogenous probabilities for the values of the exogenous variables are drawn from the prior Dirichlet distribution in accordance with a set of hyperparameters alpha.

The system samples a corresponding set of exogenous latent variables for each time step in the interaction history data given the values of the first set of parameters and the second set of parameters at the beginning of the sampling iteration (step 402). That is, if there are n total time steps across the t-1 time steps in the sequence and the time steps in the interaction histories for the source environments, the system samples a respective value u⁽ⁿ⁾ for each endogenous variable U for each of the n time steps. As a result of this sampling, the system generates the set {ū, ūₜ} where ū={u̅_{π}_{^{a}}, u̅_{π}_{^{b}}, . . . } and are the exogenous latent variable values for the time steps during the interaction of the agent with each of the one or more source environments, i.e., environments π^{a}, π^{b}, and so on, and ū=ūₓ_{⁽¹⁾}, . . . ,uₓ_{^{(t-1)}} and uₓ_{^{(t-1)}} is the exogenous latent variable values corresponding to the target environment at time step t-1.

That is, the system can independently sample a value u⁽ⁿ⁾ for each exogenous variable U⁽ⁿ⁾ from a conditional probability distribution conditioned on ξ and θ.

As a particular example, the conditional probability distribution can satisfy:

P(u⁽ⁿ⁾|v⁽ⁿ⁾,ξ,θ)∝P(u⁽ⁿ⁾,v⁽ⁿ⁾|ξ,θ)=Π_{VΣV}1{ξ_{V}^{pa}^{_{V}}^{⁽ⁿ⁾}^{,u}^{_{V}}^{⁽ⁿ⁾}=v⁽ⁿ⁾}Π_{UΣU}θᵤ,

where 1{a=b} is an indicator function that is equal to 1 when a is equal to b and zero when a is not equal to b, ξ_{V}^{pa}^{_{V}}^{⁽ⁿ⁾}^{,u}^{_{V}}^{⁽ⁿ⁾} is the first parameter corresponding to node V and argument values pa_{V}⁽ⁿ⁾ and u_{V}⁽ⁿ⁾, and θᵤ are the second parameters corresponding to node U.

The system samples the first set of parameters (step 404) using the sampled exogenous latent variables and interaction history data.

In particular, for each first parameter, the system can designate one or more of the source environments as being relevant to the environment model parameter using the relationship data and generate the value of the environment model parameter at the sampling iteration based at least in part on data characterizing interaction of the agent with each of the one or more source environments designated as being relevant to the environment model parameter.

To designate the relevant source environment(s) for a given one of the first parameters, the system can determine that the first parameter is associated with a node in the graph representing the target environment and determine, using the relationship data, whether the node in the graph representing the target environment has a relationship with a corresponding node in a graph representing a source environment. The system then only designates the source environment as being relevant to the environment model parameter when the node in the graph representing the target environment has a relationship with a corresponding node in a graph representing the source environment.

In other words, as described above, each first parameter corresponds to a respective node in the causal graph of the target environment. When sampling the value of the first parameter, the system can use only the history from the target environment and the history from any source environments for which the relationship data indicates that the functional assignment of the corresponding node is invariant between the two environments.

In particular, for a given first parameter ξ_{V}^{pa}^{_{V}}^{,u}^{_{V}} for a given variable V, and a given set of values for the endogenous arguments pay and exogenous arguments u v and a given value v for the variable V, P(ξ_{V}^{pa}^{_{V}}^{,U}^{_{V}}=v|v̅,v̅ₜ,ū,ūₜ)=1 if, there is any n across all of the time steps in the interaction of the agent with the target environment and with a relevant source environment, where v⁽ⁿ⁾=v, pa_{V}⁽ⁿ⁾=pa_{V}, and u_{V}⁽ⁿ⁾=u_{V}. Otherwise, the system can sample the value for the given first parameter uniformly at random over possible values for the given variable V.

The system samples the second set of parameters (step 406) using the sampled exogenous latent variables and the interaction history data. For example, the system can determine the respective hyperparameters of the Dirichlet distribution for a given exogenous latent variable by, for each latent variable and for each possible value of the latent variable, updating the current hyperparameter for the latent variable by summing the number of the time steps n for which (i) the sampled value matches the possible value and (ii) the corresponding environment has the same distribution over possible values of the latent variable as the target environment.

This specification uses the term “configured” in connection with systems and computer program components. For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non-transitory storage medium for execution by, or to control the operation of, data processing apparatus. The computer storage medium can be a machine-readable storage device, a machine-readable storage substrate, a random or serial access memory device, or a combination of one or more of them. Alternatively or in addition, the program instructions can be encoded on an artificially-generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application-specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program, which may also be referred to or described as a program, software, a software application, an app, a module, a software module, a script, or code, can be written in any form of programming language, including compiled or interpreted languages, or declarative or procedural languages; and it can be deployed in any form, including as a stand-alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a data communication network.

In this specification the term “engine” is used broadly to refer to a software-based system, subsystem, or process that is programmed to perform one or more specific functions. Generally, an engine will be implemented as one or more software modules or components, installed on one or more computers in one or more locations. In some cases, one or more computers will be dedicated to a particular engine; in other cases, multiple engines can be installed and running on the same computer or computers.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read-only memory or a random access memory or both. The essential elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser. Also, a computer can interact with a user by sending text messages or other forms of message to a personal device, e.g., a smartphone that is running a messaging application, and receiving responsive messages from the user in return.

Data processing apparatus for implementing machine learning models can also include, for example, special-purpose hardware accelerator units for processing common and compute-intensive parts of machine learning training or production, i.e., inference, workloads.

Machine learning models can be implemented and deployed using a machine learning framework, e.g., a TensorFlow framework, a Microsoft Cognitive Toolkit framework, an Apache Singa framework, or an Apache MXNet framework.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface, a web browser, or an app through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

While this specification contains many specific implementation details, these should not be construed as limitations on the scope of any invention or on the scope of what can be claimed, but rather as descriptions of features that can be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features can be described above as acting in certain combinations and even initially be claimed as such, one or more features from a claimed combination can in some cases be excised from the combination, and the claimed combination can be directed to a subcombination or variation of a subcombination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing can be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing can be advantageous.

Aspects of the present disclosure may be as set out in the following clauses:

What is claimed is:

1. A method performed by one or more computers, the method comprising:
selecting actions to be performed by an agent to interact with a target environment over a sequence of time steps using an environment model,
wherein the environment model is parameterized by a set of environment model parameters defining a model of the target environment,
wherein for each time step, selecting an action to be performed by the agent at the time step comprises:
sampling current values of the set of environment model parameters in accordance with a probability distribution, wherein the probability distribution is derived from a set of interaction history data, wherein the set of interaction history data comprises:
(i) data characterizing interaction of the agent with the target environment at any preceding time steps in the sequence of time steps; and
(ii) data characterizing interaction of the agent with each of one or more source environments, wherein each of the source environments are different than the target environment;
generating, using the environment model and in accordance with the current values of the set of environment model parameters, a respective expected reward for each action in a set of actions that can be performed by the agent; and
selecting the action to be performed by the agent at the time step based on the expected rewards.

2. The method of claim 1, wherein sampling current values of the set of environment model parameters in accordance with the probability distribution comprises:
generating respective values of the set of environment model parameters based on the set of interaction history data at each sampling iteration in a sequence of sampling iterations; and
designating values of the set of environment model parameters generated at a particular sampling iteration in the sequence of sampling iterations as being sampled in accordance with the probability distribution.

3. The method of claim 2, wherein the values of the set of environment model parameters generated at each sampling iteration in the sequence of sampling iterations define a Markov chain with an invariant distribution given by the probability distribution.

4. The method of claim 2, further comprising obtaining relationship data that characterizes a respective relationship between the target environment and each of the source environments;
wherein at each sampling iteration, generating values of the set of environment model parameters based on the set of interaction history data comprises:
generating values of the set of environment model parameters based on: (i) the set of interaction history data, and (ii) the relationship data.

5. The method of claim 4, wherein the target environment and each of the source environments can be represented by respective graphs; and
wherein for each source environment, the relationship data defines a correspondence between one or more nodes in the graph representing the target environment with corresponding nodes in the graph representing the source environment.

6. The method of claim 5, wherein each node in the graph representing the target environment represents a respective element of the target environment.

7. The method of claim 6, wherein one or more nodes in the graph representing the target environment represent respective features of the target environment.

8. The method of claim 6, wherein a first node in the graph representing the target environment represents respective actions performed by the agent in the target environment.

9. The method of claim 6 wherein a second node in the graph representing the target environment represents respective rewards received as a result of actions performed by the agent in the target environment.

10. The method of claim 5, wherein at each sampling iteration, generating values of the set of environment model parameters based on: (i) the set of interaction history data, and (ii) the relationship data comprises, for each of one or more environment model parameters:
designating one or more of the source environments as being relevant to the environment model parameter using the relationship data; and
generating the value of the environment model parameter based at least in part on data characterizing interaction of the agent with each of the one or more source environments designated as being relevant to the environment model parameter.

11. The method of claim 10, wherein designating one or more of the source environments as being relevant to the environment model parameter using the relationship data comprises:
determining that the environment model parameter is associated with a node in the graph representing the target environment;
determining, using the relationship data, that the node in the graph representing the target environment has a relationship with a corresponding node in a graph representing a source environment; and
in response, designating the source environment as being relevant to the environment model parameter.

12. The method of claim 1, further comprising, at each time step:
augmenting the set of interaction history data with data characterizing interaction of the agent with the target environment at the time step.

13. The method of claim 1, wherein for each time step, selecting the action to be performed by the agent at the time step based on the expected rewards comprises:
selecting an action having a highest expected reward from among the set of actions.

14. The method of claim 1, wherein for each time step, selecting the action to be performed by the agent at the time step based on the expected rewards comprises:
determining a probability distribution over the set of actions using the expected rewards; and
sampling an action in accordance with the probability distribution over the set of actions.

15. The method of claim 1, wherein for each source environment, the data characterizing the interaction of the agent with the source environment comprises a plurality of experience tuples, wherein each experience tuple comprises:
(i) an observation characterizing a state of the source environment,
(ii) an action performed by the agent in response to the observation; and
(iii) a reward received by the agent as a result of performing the action.

16. A system comprising:
one or more computers; and
one or more storage devices communicatively coupled to the one or more computers, wherein the one or more storage devices store instructions that, when executed by the one or more computers, cause the one or more computers to perform operations comprising:
selecting actions to be performed by an agent to interact with a target environment over a sequence of time steps using an environment model,
wherein the environment model is parameterized by a set of environment model parameters defining a model of the target environment,
wherein for each time step, selecting an action to be performed by the agent at the time step comprises:
sampling current values of the set of environment model parameters in accordance with a probability distribution, wherein the probability distribution is derived from a set of interaction history data, wherein the set of interaction history data comprises:
(i) data characterizing interaction of the agent with the target environment at any preceding time steps in the sequence of time steps; and
(ii) data characterizing interaction of the agent with each of one or more source environments, wherein each of the source environments are different than the target environment;
generating, using the environment model and in accordance with the current values of the set of environment model parameters, a respective expected reward for each action in a set of actions that can be performed by the agent; and
selecting the action to be performed by the agent at the time step based on the expected rewards.

17. The system of claim 16, wherein sampling current values of the set of environment model parameters in accordance with the probability distribution comprises:
generating respective values of the set of environment model parameters based on the set of interaction history data at each sampling iteration in a sequence of sampling iterations; and
designating values of the set of environment model parameters generated at a particular sampling iteration in the sequence of sampling iterations as being sampled in accordance with the probability distribution.

18. The system of claim 17, wherein the values of the set of environment model parameters generated at each sampling iteration in the sequence of sampling iterations define a Markov chain with an invariant distribution given by the probability distribution.

19. The system of claim 17, wherein the operations further comprise obtaining relationship data that characterizes a respective relationship between the target environment and each of the source environments;
wherein at each sampling iteration, generating values of the set of environment model parameters based on the set of interaction history data comprises:
generating values of the set of environment model parameters based on: (i) the set of interaction history data, and (ii) the relationship data.

20. One or more non-transitory computer storage media storing instructions that when executed by one or more computers cause the one or more computers to perform operations comprising:
selecting actions to be performed by an agent to interact with a target environment over a sequence of time steps using an environment model,
wherein the environment model is parameterized by a set of environment model parameters defining a model of the target environment,
wherein for each time step, selecting an action to be performed by the agent at the time step comprises:
sampling current values of the set of environment model parameters in accordance with a probability distribution, wherein the probability distribution is derived from a set of interaction history data, wherein the set of interaction history data comprises:
(i) data characterizing interaction of the agent with the target environment at any preceding time steps in the sequence of time steps; and
(ii) data characterizing interaction of the agent with each of one or more source environments, wherein each of the source environments are different than the target environment;
generating, using the environment model and in accordance with the current values of the set of environment model parameters, a respective expected reward for each action in a set of actions that can be performed by the agent; and
selecting the action to be performed by the agent at the time step based on the expected rewards.
